(19) United States
(12) Patent Application Publication
(10) Pub. No.: US 2026/0114234 A1
(43) Pub. Date: Apr. 23, 2026

(54) LIFT PIN ASSEMBLY FOR SUBSTRATE PROCESSING CHAMBER

(71) Applicant: Applied Materials, Inc., Santa Clara, CA (US)

(72) Inventors: Jian HUA, Wuxi City, Jiangsu Province (CN); Dahan QIAN, Hefei, Anhui Province (CN); Changjun SHEN, Pudong New Area, Shanghai (CN); Menglan SHEN, Pudong New Area, Shanghai (CN); Yue YANG, Hefei, Anhui Province (CN)

(73) Assignee: Applied Materials, Inc., Santa Clara, CA (US)

(21) Appl. No.: 18/866,375

(22) PCT Filed: Oct. 23, 2024
(86) PCT No.: PCT/CN2024/126760

§ 371 Date: Nov. 15, 2024

(51) Int. Cl. H10P 72/76

(52) U.S. Cl. CPC H10P 72/7612

(57) ABSTRACT

Lift pin assemblies and substrate processing chambers including the lift pin assemblies are disclosed. The lift pin assembly comprises outer lift pins movable by an outer lift platform, the outer lift pins positioned to raise and lower through and outer periphery of a substrate support. The lift pin assembly further comprises inner lift pins movable by an inner lift platform, the inner lift pins positioned to raise and lower through an inner periphery of the substrate support, the inner lift pins and the outer lift pins positioned and configured to raise and lower a warped substrate from the substrate support.

### TECHNICAL FIELD

Embodiments of the disclosure generally relate apparatus for handling a substrate, for example a semiconductor substrate such as a wafer. In particular, embodiments of disclosure relate to a lift pin assembly.

### BACKGROUND

Lift pins extend through a substrate support, such as a pedestal, to lift a substrate off the substrate support to facilitate placement and removal of the substrate onto the substrate support. Bowed or warped substrates create challenges in handling of the substrate.

FIGS. 1A-B and 2A-D illustrate problems encountered in handling a bowed or warped substrate In an existing substrate support and lift pin assembly 100 in an existing design within a substrate processing chamber 180. In the existing design shown in FIGS. 1A-B, the substrate support 102 (or pedestal) comprises an outer region 102o, an inner region 102i and a center point 102c. Outer peripheral resting pins 110 and inner resting pins 120 are fixed in place by an or-ring 121 in the substrate support 102 and do not move up or down vertically. Lift pins 130 positioned intermediate to the outer peripheral resting pins 110 and inner resting pins 120 are mounted to a platform 135 connected to a shaft 137 coupled to a lift mechanism 140. When the lift mechanism moves the shaft upwardly or downwardly as indicated by arrow 160, the lift pins 130 raise and lower a substrate from the from the outer peripheral resting pins 110 and inner resting pins 120 as indicated by the arrow 160.

However, if the substrate 150u is bowed or warped upwardly as shown in FIGS. 2A and 2B, when the substrate 150u that is bowed or warped upwardly is lowered, not all of the outer peripheral resting pins 110 and inner resting pins 120 contact the substrate 150u, and this causes the wafer to slide or move off the center point 102c of the substrate support 102. In FIGS. 3A-B, a substrate 150d that is downwardly bowed or warped is shown. Again, when the substrate 150d that is bowed or warped downwardly is lowered, not all of the outer peripheral resting pins 110 and inner resting pins 120 contact the substrate 150u, and this causes the wafer to slide or move off the center point 102c of the substrate support 102.

Accordingly, there is a need for resting pin assemblies that are configured to handle bowed or warped substrates so that the substrates are maintained in a centered position on the substrate support.

### SUMMARY

One or more embodiments of the disclosure are directed to a lift pin assembly comprising outer lift pins movable by an outer lift platform, the outer lift pins positioned to raise and lower through and outer periphery of a substrate support; and inner lift pins movable by an inner lift platform, the inner lift pins positioned to raise and lower through an inner periphery of the substrate support, the inner lift pins and the outer lift pins positioned and configured to raise and lower a warped substrate from the substrate support.

Some embodiments comprise inner lift pin force sensors and outer lift pin force sensors and a controller configured to control raising and lowering of the outer lift platform and the inner lift platform.

Another embodiment of the disclosure pertains to a substrate processing chamber comprising the lift pin assemblies according to one or more embodiments. Another aspect of the disclosure pertains to a processing method comprising raising and lowering a warped substrate in using the lift pin assemblies described herein. In particular embodiments, the method is performed in a substrate processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. The appended drawings illustrate specific embodiments of this disclosure and are therefore not to be considered limiting of its scope, for the disclosure may admit to other equally effective embodiments.

FIG. 1A shows a top plan view of a prior art substrate support and lift pin assembly;

FIG. 18 shows a cross-sectional side elevation view of the substrate support and lift pin assembly show in FIG. 1A;

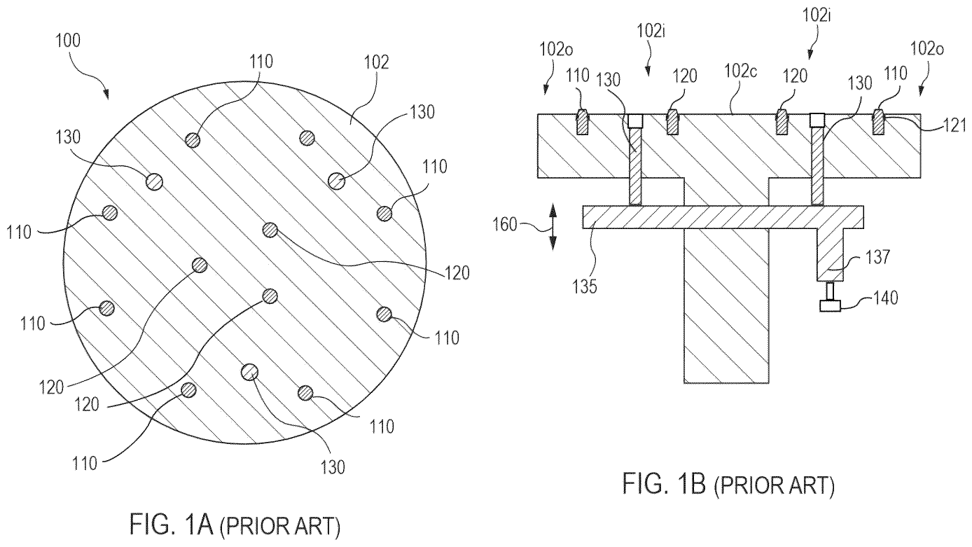

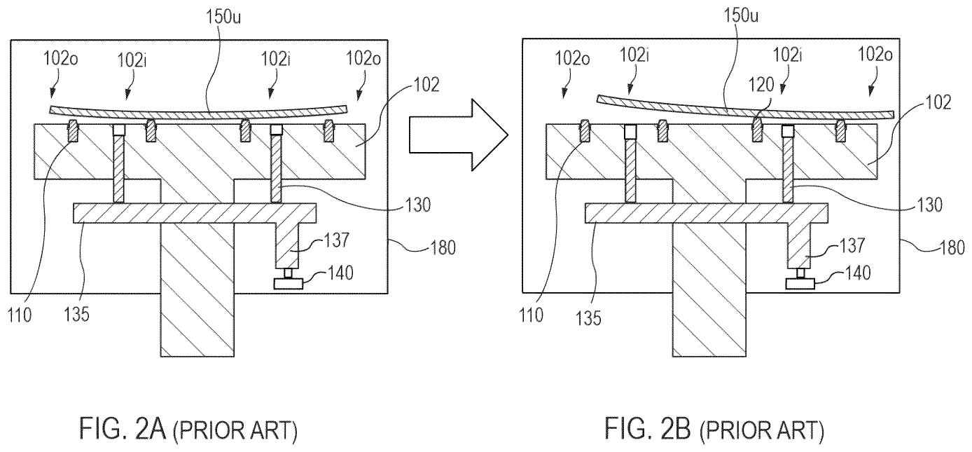

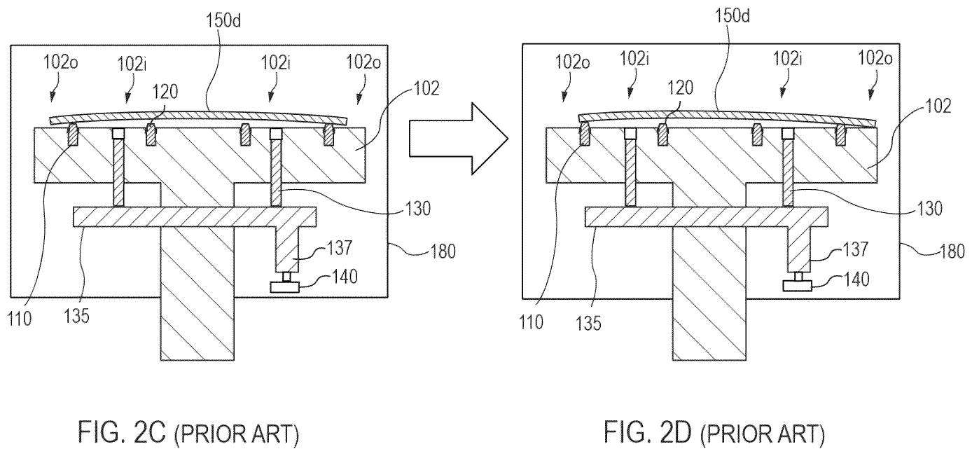

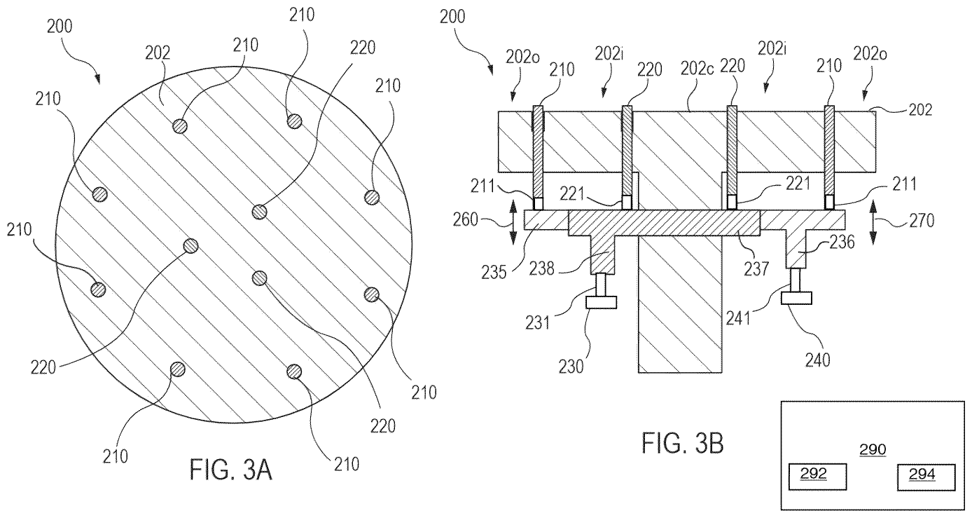

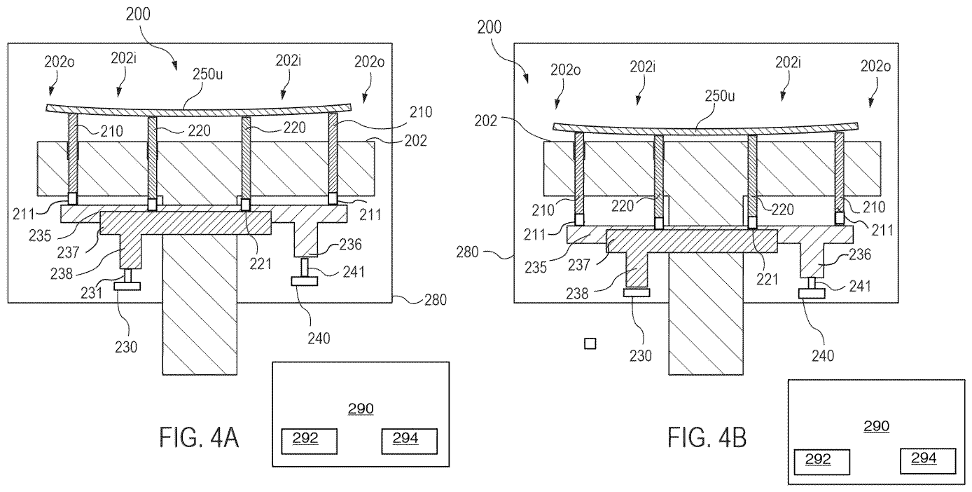

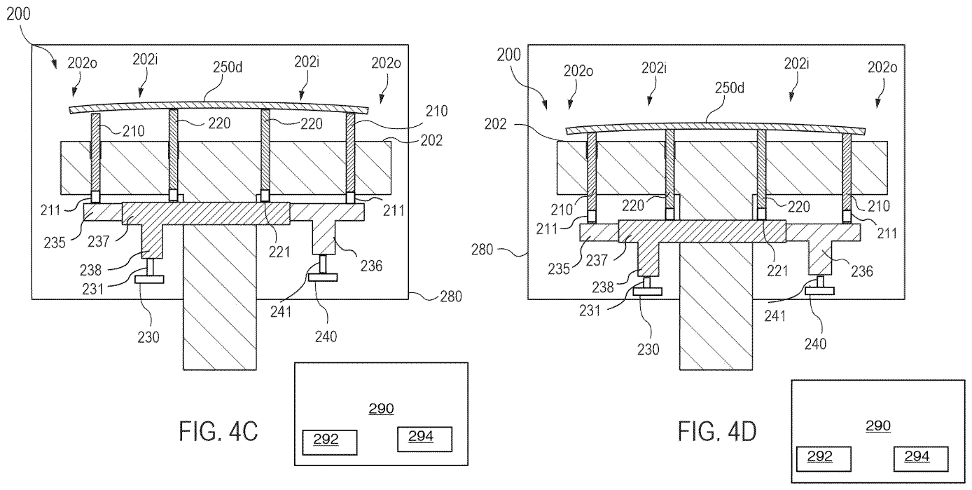

FIG. 2A shows a cross-sectional side elevation view of the substrate support and lift pin assembly shown in FIG. 1A supporting an upwardly bowed substrate;

FIG. 2B shows a cross-sectional side elevation view of the substrate support and lift pin assembly shown in FIG. 2A with the upwardly bowed substrate moved off the substrate support;

FIG. 2C shows a cross-sectional side elevation view of the substrate support and lift pin assembly shown in FIG. 1A with a downwardly bowed substrate;

FIG. 2D shows a cross-sectional side elevation view of the substrate support and lift pin assembly shown in FIG. 2C with the downwardly bowed substrate moved off the substrate support;

FIG. 3A shows a top plan view of a prior art substrate support and lift pin assembly according to an embodiment of the disclosure;

FIG. 3B shows a cross-sectional side elevation view of the substrate support and lift pin assembly show in FIG. 3A;

FIG. 4A shows a cross-sectional side elevation view of the substrate support and lift pin assembly shown in FIG. 3A supporting an upwardly bowed substrate;

FIG. 4B shows a cross-sectional side elevation view of the substrate support and lift pin assembly shown in FIG. 2B with the upwardly bowed substrate stably supported by the substrate support and lift pin assembly;

FIG. 4C shows a cross-sectional side elevation view of the substrate support and lift pin assembly shown in FIG. 3A with a downwardly bowed substrate; and

FIG. 4D shows a cross-sectional side elevation view of the substrate support and lift pin assembly shown in FIG. 4C with the downwardly bowed substrate stably supported by the substrate support and lift pin assembly.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” (also referred to as a “wafer”) as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor substrates, Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

As used in this specification and the appended claims, “substrate processing chamber” refers to an enclosed chamber that is configured to conduct one or more processes on a substrate, for example a wafer, a semiconductor wafer or an electronic device in an initial stage or later stage of electronic device manufacturing. The substrate processing chamber can be a chemical vapor deposition (CVD) chamber, a cyclical vapor deposition chamber, an atomic layer deposition (ALD) chamber, a physical vapor deposition (PVD) chamber or pass through and cooling chamber.

The substrate processing chamber may include the capability to form or deliver a plasma. A substrate processing chamber according to one or more embodiments may be configured to perform a heating, annealing cleaning, and or etching process.

FIGS. 4A-D illustrate a lift pin assembly 200 used in a substrate processing chamber 280 in accordance with one or more embodiments of the disclosure. As used in this manner, an “assembly” refers to a combination of components or parts.

The lift pin assembly 200 shown in FIG. 3A-B comprises outer lift pins 210 movable by an outer lift platform 235 including an outer lift shaft 236, As shown, the outer lift pins 210 positioned to raise and lower through an outer periphery 202o of a substrate support 202. The outer lift pins 210 may be mounted to the outer lift platform 235 by any suitable way. For example, the outer lift pins 210 may be adhesively affixed to the outer lift platform 235. In other example, the outer lift pins 210 may be welded or soldered to the outer lift platform 235. In some embodiments, the outer lift pins 210 are assembled to the outer lift platform by threading the outer lift pins 210 to the outer lift platform 235.

The lift pin assembly 200 further comprises inner lift pins 220 movable by an inner lift platform 237 including an inner lift shaft 238. The inner lift pins 220 are positioned to raise and lower through an inner periphery 220i of the substrate support 202. The inner periphery 202i is closer to a center 202c of the substrate support 202. The inner lift pins 220 may be mounted to the inner lift platform 237 by any suitable way. For example, the inner lift pins 220 may be adhesively affixed to the inner lift platform 237. In other example, the inner lift pins 220 may be welded or soldered to the inner lift platform 237. In some embodiments, the inner lift pins 220 are assembled to the inner lift platform 237 by threading the inner lift pins 220 to the inner lift platform 237.

The inner lift pins 220 and the outer lift pins 210 are positioned and configured to stably raise and lower a warped substrate from the substrate support 202. As used herein according to one or more embodiments, “stably” refers to the lift pin assembly 200 being configured to raise and lower an upwardly warped substrate in the direction of arrows 260 and 270 without the substrate sliding, tilting and with the substrate being centered on with respect to the center 202c of the substrate support.

In one or more embodiments of the lift pin assembly 200, the outer lift pins 210 are configured to be independently raised and lowered with respect to the inner lift pins 220. What this means is that while the inner lift pins 220 are moving, the outer lift pins 210 are not moving, or alternatively, while the outer lift pins 210 are moving, the inner lift pins 220 are not moving. However, in some embodiments, the outer lift pins 210 and the inner lift pins 220 may move at the same time, but at a different rate of moving. A controller 290, described further below, is configured to control independent movement of the outer lift pins 210 that move with the outer lift platform 235 and the inner lift pins 220 that move with the inner lift platform 237.

The lift pin assembly 200 according to one or more embodiments further comprises an outer lift mechanism 240 configured to raise and lower the outer lift platform 235 and an inner lift mechanism 230 configured to raise and lower the inner lift platform 237. In the embodiment shown, the outer lift mechanism 240 comprises an outer lift rod 241 and an outer motor. Similarly, the inner lift mechanism 230 comprises an inner lift rod 231 and an inner motor.

According to one or more embodiments of the lift pin assembly 200, the outer lift platform 235 is ring-shaped and the inner lift platform 237 is ring-shaped. In one or more embodiments of the lift assembly, the outer motor comprises a servo motor and the inner motor comprises a servo motor.

The lift pin assembly 200 of one or more embodiments includes a controller 290 configured to control raising and lowering of the outer lift mechanism 240 and the inner lift mechanism 230. In some embodiments, the controller 290 is configured control raising and lowering of the outer lift mechanism 240 independently from the inner lift mechanism 230.

The lift pin assembly 200 according to the embodiment shown further comprises inner lift pin force sensors 221 in contact with the inner lift pins 220. While shown at a lower end of the Inner lift pins 220, the lift pin force sensors can be located at the upper end of the inner lift pins.

The lift pin assembly 200 in the embodiment shown further comprises outer lift pin force sensors 211. The outer lift pin force sensors 211 are shown as being in contact with a lower portion of the outer lift pins 210, however, the outer lift pin force sensors 211 can also be located at the upper portion of the outer lift pins 210.

The lift pin assembly 200 according to one or more embodiments is configured so that the outer lift pin force sensors 211 and the inner lift pin force sensors 221 are in communication with the controller 290. The communication can be in wired communication or wireless communication so that the controller 290 receive force signals from the outer lift pin force sensors 211 and the inner lift pin force sensors 221.

In one or more embodiments of the lift pin assembly 200, the outer lift pin force sensors 211 are configured to communicate to the controller 290 a force set point corresponding to when the outer lift pins 210 are in contact with a substrate 250u or 250d. For example, as shown in FIGS. 4A and 4B, the inner lift pins 220 are raised to a lesser extent than the outer lift pins 210 for an upwardly warped substrate 250u. Thus, when processing an upwardly warped substrate 250u and the upwardly warped substrate 250u is raised, the inner lift pin force sensors 221 are configured to send a signal to the controller 290 when the inner lift pin force sensors 221 sense or detect a predetermined force when the inner lift pins 220 contact the upwardly warped substrate 250u. The outer lift pins 210 may continue moving upwardly after the inner lift pins 220 have stopped moving, and the outer lift pins 210 will stop when the outer lift pin force sensors 211 sense a predetermined force value that indicates that outer lift pins 210 are in contact with the upwardly warped substrate.

Thus, the inner lift pin force sensors 221 are configured to communicate to the controller 290 a force set point corresponding to when the inner lift pins 220 are in contact with the substrate 250u or 250d. The controller 290 is configured to stop movement of the outer lift pins 210 when the outer lift pins 210 contact the substrate 250u or 250d. The controller 290 is configured to stop movement of the inner lift pins 210 when the inner lift pins 210 contact the substrate 250u or 250d. Advantageously, the lift pin assembly 200 is configured to raise and lower an upwardly warped substrate 250u from the substrate support 202 as shown in FIGS. 4A and 4B.

Turning now to FIGS. 4C and 4D, the lift pin assembly 200 is configured to raise and lower a downwardly warped substrate 250d from the substrate support 202. In the embodiment shown, when processing a downwardly warped substrate 250d, the outer lift pins 210 will stop first when the outer lift pin force sensors 211 send a signal to the controller that a predetermined force signal has been sensed or measured by the outer lift pin force sensors. The inner lift pins 220 will continue to travel to a greater extent until they contact the inner periphery 202i of the downwardly warped substrate 250d. Once contact is made, the inner lift pin force sensors 221 will send a signal to the 8 controller that a predetermined force value has been reached that correlates with the inner lift pins 220 contacting the downwardly warped substrate 250d.

Thus, some embodiments of the lift pin assembly 200 include a controller 290 coupled to various components of the substrate processing chamber 280 to control the operation thereof. The controller 290 of some embodiments controls the entire substrate processing chamber 280 or separately controls the lift pin assembly 200. In some embodiments, the substrate processing chamber 280 includes multiple controllers 290, each configured to control one or more individual portions of the substrate processing chamber 280. For example, the substrate processing chamber 280 of some embodiments comprises separate controllers for one or more of operation of the substrate processing chamber 280, the outer lift pins 210 and the inner lift pins 220. In some embodiments, at least one controller 290 is coupled to one or more of the processing chamber 280, the substrate support 202, the lift pin assembly 200 or other components used for the operation of the substrate processing chamber 280.

The controller 290 may be one of any form of general-purpose computer processor, microcontroller, microprocessor, etc., that can be used in an industrial setting for controlling various chambers and sub-processors. The controller 290 of some embodiments has a processor 292, a memory 294 coupled to the processor 292, input/output devices (not shown) coupled to the processor 292, and support circuits (not shown) configured to communicate between the different electronic components. The memory 294 of some embodiments includes one or more of transitory memory (e.g., random access memory) and non-transitory memory (e.g., storage).

The memory 294, or a computer-readable medium, of the processor may be one or more of readily available memory such as random access memory (RAM), read-only memory (ROM), floppy disk, hard disk, or any other form of digital storage, local or remote. The memory 294 can retain an instruction set that is operable by the processor 292 to control parameters and components of the system. The support circuits are coupled to the processor 292 for supporting the processor in a conventional manner. Support circuits may include, for example, cache, power supplies, clock circuits, input/output circuitry, subsystems, and the like.

Processes may generally be stored in the memory 294 as a software routine that, when executed by the processor, causes the process chamber to perform processes of the present disclosure, The software routine may also be stored and/or executed by a second processor (not shown) that is remotely located from the hardware being controlled by the processor. Some or all of the methods of the present disclosure may also be performed in hardware. As such, the methods may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

The inner lift pin force sensors 221 and the outer lift pin force sensors 211 may comprises contact force sensors, which are configured to determine a contact force applied between the substrate 250u or 250d and the inner lift pins 220 and the outer lift pins 210, by measuring the contact forces therebetween. Thus, the contact force sensors that are used may comprise any sensors suitable for measuring contact forces between the substrate 250u or 250d and the substrate contacting surfaces of the outer lift pins 210 and the inner lift pins 220. Examples of suitable sensors include piezo-electric sensors, piezo-resistive sensors, micro-electro-mechanical (MEMS) sensors, such as MEMS load cells, and combinations thereof. In some embodiments, the contact force sensors comprise thin film sensors having a thickness of less than about 100 μm; less than about 50 μm, for example less than about 25 μm.

The outer lift mechanism 240 and the inner lift mechanism 230 may include a servo motor, a linear motor, a rotary motor, a stepper motor or other suitable device for imparting movement in the inner lift rod 231 and the outer lift rod 241 at a micrometer scale. The outer lift mechanism 240 and the inner lift mechanism 230 respectively directly drives the outer lift rod 241 and the inner lift rod 231, i.e., move the lift rods up and down. The outer lift rod 241 and the inner lift rod 231 may be any suitable rod such as a threaded rod, a tubular rod, rectangular bar, or any suitable ridged member for imparting movement.

In some embodiments, both the outer lift pins 219 and the inner lift pins 210 are electrically and/or thermally conductive. The use of conductive materials for the lift pins prevents charge building during processing which can lead to the lift pins sticking. Some embodiments prevent non-uniform chucking of incoming substrates by grounding the substrate until it is fully seated on the substrate support 202. Additionally, conductive lift pins ground and discharge electrical charge from the substrate for an outgoing substrate.

In some embodiments, a non-transitory computer readable medium includes instructions, that, when executed by the controller 290 of the substrate processing chamber 280, causes the processing chamber to perform operations of independently raising and lowering a group of inner lift pins 220 and outer lift pins 210. The non-transitory computer readable medium may further include instructions, that, when executed by the controller 290 to receive force values from inner lift pin force sensors 221 and outer lift pin force sensors 211, and in response to receiving the force values that indicate that outer lift pins 210 and inner lift pins 220 have contacted a substrate to stop movement of the outer lift pins 210 and the inner lift pins.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

1. A lift pin assembly comprising:
outer lift pins movable by an outer lift platform, the outer lift pins positioned to raise and lower through an outer periphery of a substrate support; and
inner lift pins movable by an inner lift platform, the inner lift pins positioned to raise and lower through an inner periphery of the substrate support, the inner lift pins and the outer lift pins positioned and configured to raise and lower a warped substrate from the substrate support.

2. The lift pin assembly of claim 1, wherein the outer lift pins are configured to be independently raised and lowered with respect to the inner lift pins.

3. The lift pin assembly of claim 2, further comprising an outer lift mechanism configured to raise and lower the outer lift platform and an inner lift mechanism configured to raise and lower the inner lift platform.

4. The lift pin assembly of claim 3, wherein the outer lift mechanism is ring-shaped and the inner lift mechanism is ring-shaped.

5. The lift pin assembly of claim 3, wherein the outer lift mechanism comprises an outer lift rod and an outer motor.

6. The lift pin assembly of claim 4, wherein the inner lift mechanism comprises an inner lift rod and an inner motor.

7. The lift pin assembly of claim 6, wherein the outer motor comprises a servo motor and the inner motor comprises a servo motor.

8. The lift pin assembly of claim 6, further comprising a controller configured to control raising and lowering of the outer lift mechanism and the inner lift mechanism.

9. The lift pin assembly of claim 8, wherein the controller is configured control raising and lowering of the outer lift mechanism independently from the inner lift mechanism.

10. The lift pin assembly of claim 9, further comprising inner lift pin force sensors.

11. The lift pin assembly of claim 10, further comprising outer lift pin force sensors.

12. The lift pin assembly of claim 11, wherein the outer lift pin force sensors and the inner lift pin force sensors are in communication with the controller.

13. The lift pin assembly of claim 12, wherein the outer lift pin force sensors are configured to communicate to the controller a force set point corresponding to when the outer lift pins are in contact with a substrate.

14. The lift pin assembly of claim 13, wherein the inner lift pin force sensors are configured to communicate to the controller a force set point corresponding to when the inner lift pins are in contact with the substrate.

15. The lift pin assembly of claim 14, wherein the controller is configured to stop movement of the outer lift pins when the outer lift pins contact the substrate.

16. The lift pin assembly of claim 15, wherein the controller is configured to stop movement of the inner lift pins when the inner lift pins contact the substrate.

17. The lift pin assembly of claim 16, wherein the lift pin assembly is configured to raise and lower an upwardly warped substrate from the substrate support.

18. The lift pin assembly of claim 16, wherein the lift pin assembly is configured to raise and lower a downwardly warped substrate from the substrate support.

19. A substrate processing chamber comprising the lift pin assembly according to claim 1, wherein the lift pin assembly is contained within the substrate processing chamber.

20. A processing method comprising raising and lowering a warped substrate in the substrate processing chamber of claim 19.
